(19) United States
(12) Patent Application Publication
(10) Pub. No.: US 2024/0088283 A1
(43) Pub. Date: Mar. 14, 2024

(54) ULTRALOW NOISE TRANSISTOR AMPLIFIERS VIA IMPROVED QUANTUM CONFINEMENT

(71) Applicant: California Institute of Technology, Pasadena, CA (US)

(72) Inventors: Austin Minnich, San Marino, CA (US); Iretomiwa Esho, Pasadena, CA (US); Bekari Gabritchidze, Pasadena, CA (US); Kieran A. Cleary, Pasadena, CA (US)

(73) Assignee: California Institute of Technology, Pasadena, CA (US)

(21) Appl. No.: 18/465,902

(22) Filed: Sep. 12, 2023

Related U.S. Application Data
(60) Provisional application No. 63/405,799, filed on Sep. 12, 2022.

(51) Int. Cl. H01L 29/778; H01L 27/088; H01L 29/08; H01L 29/20; H01L 29/66

(52) U.S. Cl. CPC H01L 29/7786; H01L 27/088; H01L 29/0865; H01L 29/0882; H01L 29/2003; H01L 29/66431; H01L 29/66462; H01L 29/7783

(57) ABSTRACT

A high electron mobility transistor (HEMT) including a channel; a barrier confining mobile charge carriers in the channel; a drain contact to the channel; a source contact to the channel; and a gate contact coupled to the channel and modulating a current, comprising the mobile charge carriers flowing in response to a voltage V_{SD} applied between the source contact and the drain contact, when an RF signal electric field and DC bias electric field are applied between the gate contact and the source contact. An offset between the conduction bands of the channel and barrier is increased to a level that suppresses real space transfer noise associated with a portion of the mobile charge carriers being thermionically emitted out of the channel into the barrier when the V_{SD} is applied, wherein the RST noise is reduced by at least a factor of two as compared to a HEMT where the alloy composition of the barrier is lattice matched.

### CROSS REFERENCE TO RELATED APPLICATIONS

This application claims the benefit under 35 U.S.C. Section 119(e) of co-pending and commonly-assigned U.S. Provisional Patent Application Ser. No. 63/405,799, filed on Sep. 12, 2022, by Austin Minnich, Iretomiwa Esho, Bekari Gabritchidze, and Kieran K. Cleary, entitled “ULTRALOW NOISE TRANSISTOR AMPLIFIERS VIA IMPROVED QUANTUM CONFINEMENT” (CIT 8876); which application is incorporated by reference herein.

### STATEMENT REGARDING FEDERALLY SPONSORED RESEARCH AND DEVELOPMENT

This invention was made with government support under Grant No. AST1911220 awarded by the National Science Foundation. The government has certain rights in the invention.

### BACKGROUND OF THE INVENTION

### 1. Field of the Invention

The present disclosure relates to HEMTs and methods of making the same.

### 2. Description of the Related Art

High electron mobility transistors (HEMTs) based on InGaAs quantum wells are widely used in applications including radio astronomy and quantum computing. Due to the importance of achieving low receiver noise in these applications, there exists significant interest in the physical origins of the microwave noise and methods to mitigate them. Microwave noise in HEMTs is typically described using the Pospieszalski model in which noise generators are specified at the gate and drain of the HEMT. The gate noise generator is attributed to thermal noise in the gate metal, but the drain noise generator lacks an accepted physical origin. This drain noise (T_{d}) dominates the total noise and sets the lowest limit of achievable noise in HEMTs. What is needed are reduced noise HEMTs. The present disclosure satisfies this need.

### SUMMARY OF THE INVENTION

A HEMT including a channel; a barrier confining mobile charge carriers in the channel; a drain contact to the channel; a source contact to the channel; and a gate contact coupled to the channel and modulating a current, comprising the mobile charge carriers flowing in response to a voltage V_{SD} applied between the source contact and the drain contact, when an RF signal electric field and DC bias electric field are applied between the gate contact and the source contact. The alloy compositions of the both the channel and the barrier can be selected to that the offset, between the conduction bands of the channel and barrier, is increased to a level that suppresses real space transfer noise (RST) associated with a portion of the mobile charge carriers being thermionically emitted out of the channel into the barrier when the V_{SD} is applied. In one or more examples, the RST noise is reduced by at least a factor of two as compared to a HEMT where the alloy composition of the barrier is lattice matched (e.g., to the substrate, or to In_{0.52}Al_{0.48}As in the case of an InGaAs/InAlAs HEMT). In one or more further examples, at 300 Kelvin (K), the RST noise can be zero (eliminated) or reduced (e.g., by a factor of at least two) as compared to the channel thermal noise under low noise bias conditions (V_{DS} and V_{GS} selected to minimize noise).

### BRIEF DESCRIPTION OF THE DRAWINGS

Referring now to the drawings in which like reference numbers represent corresponding parts throughout:

FIG. 1. Schematic of a HEMT according to one or more embodiments.

FIG. 2. Schematic of a HEMT band structure according to one or more embodiments.

FIG. 3. Schematic of a cryogenic probe station configured for microwave noise measurements. The cryogenic and room temperature parts are separated by a radiation shield and stainless-steel coaxial cables. A heater and a temperature sensor are placed on the chuck and enable temperature control of the device. Two different noise powers are generated by the noise source, that then propagate through the coaxial system and the device. The two power levels are processed and measured at the intermediate frequency stage and allow the determination of the noise of the device through the Y-factor method.

FIG. 4. Extracted drain temperature T_{d} (black circles) versus physical temperature Tₚₕ at constant V_{DS}=0.6 V and I_{DS}=10 mA. The electron physical temperature Tₑₗ (red dashed line and diamond marker) and the real space transfer part T_{RST} (blue dashed dot line cross marker).

FIG. 5 Modeled Tₘᵢₙ and predicted Tₘᵢₙ without RST versus physical temperature at constant V_{DS}=0.6 V and I_{DS}=10 mA (a), and versus V_{DS} as at 40 K (b) and 300 K (c) at constant V_{GS}=−136 mV and V_{GS}=−226 mV, respectively. The predicted Tₘᵢₙ is modeled by replacing the extracted T_{d} with Tₑₗ (i.e. T_{RST}=0) in the noise model. All the data are at the frequency of 6 GHz. The V_{GS} in (b) and (c) were selected so that at both physical temperatures, V_{DS}=0.8 V and I_{DS}=20 mA.

FIG. 6. Schematic of a typical receiver system, with a dish, low noise amplifier and signal detection unit. The low noise amplifier is the first electrical component that the incoming signal interacts with. The low noise amplifier adds its own noise to the incoming signal and determines the resolution of the detected signal. It is therefore crucial that the noise generated within the low noise amplifier is minimal. Typical low noise amplifier is made of two or more high electron mobility transistors (HEMTs), matching networks and bias lines.

FIG. 7. Flow chart illustrating a method of making a HEMT according to one or more embodiments.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

Theoretical and experimental evidence of the physical mechanisms for the origin of drain noise can be provided in terms of thermal and real-space transfer (RST) noise. The thermal part of drain temperature is Johnson noise associated with heated electrons in the channel. The RST part arises because heated electrons in the channel are thermionically emitted out of the channel into the barrier film, leading to a form of partition noise. Our measurements indicate that RST noise comprises over half of the total amplifier noise at room temperature.

RST takes place when electrons gain sufficient thermal energy to thermionically emit over the conduction band discontinuity between the channel and barrier. This conduction band discontinuity (ΔE_{C}) depends on the semiconductor materials used for the channel and the barrier layer. Thus, the inventors have found that RST can be controlled by increasing the size of the discontinuity to suppress the thermionic emission.

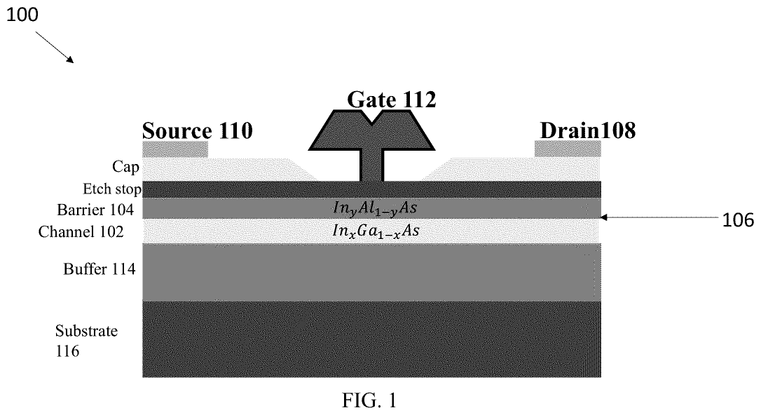

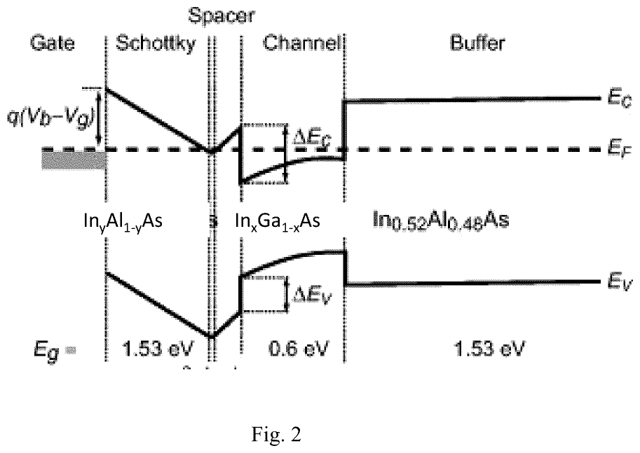

FIG. 1 and FIG. 2 illustrate a HEMT 100 according to one or more embodiments, comprising a channel layer 102 comprising a first semiconductor alloy (e.g., InGaAs) comprising a first conduction band energy Ec; and a barrier layer 104 comprising a second semiconductor alloy (e.g., InAlAs) comprising a second conduction band energy Ec. A heterojunction 106 is formed between the first semiconductor alloy and the second semiconductor alloy and an offset ΔEc between the first conduction band energy and the second conduction band energy confines mobile charge carriers (e.g., two dimensional electron gas, 2DEG) in the channel. Also shown in FIG. 1 are cap layer, etch stop layer, buffer layer 114 and substrate 116.

The HEMT further comprises a drain ohmic contact 108 to the channel; a source ohmic contact 110 to the channel; and a gate contact 112 coupled to the channel and modulating a current, comprising the mobile charge carriers flowing in response to a voltage V_{SD} applied between the source contact and the drain contact, when a radio frequency (RF) signal electric field and a direct current (DC) bias electric field are applied between the gate contact and the source contact.

The first alloy composition of the first semiconductor alloy and/or the second alloy composition of the semiconductor alloy are selected so that the offset ΔEc is increased to a level that suppresses real space transfer (RST) noise associated with a portion of the mobile charge carriers being thermionically emitted out of the channel into the barrier when the V_{SD} is applied. The offset is typically set so that the RST noise is reduced by at least a factor of two as compared to a HEMT where the alloy composition of the barrier is lattice matched. In some embodiments, the RST can be reduced to zero.

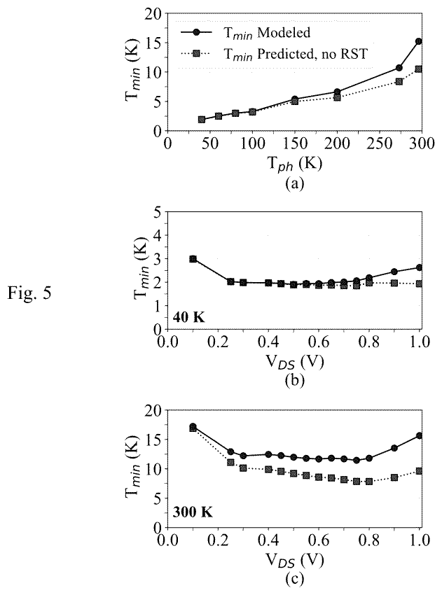

In one or more examples, the microwave noise temperature at 6 GHz of at least 7K (or 7K-14K) for V_{SD} in a range of 0.1-1.2 V and Tph of 300K can be achieved, when the transistor is optimally noise matched to a 50 Ohm load and the RF signal electric field is 1-20 GHz (as shown in FIG. 5 for an InGaAs/InAlAs HEMT). At frequencies of 6 or 8 GHz or less, the microwave noise temperature can be as low as 1 K.

Alternatively stated, an ideal HEMT contributes only Johnson noise, rather than both Johnson and RST noise, or the HEMT would have RST noise which is much less than the channel thermal noise component of the Johnson noise (considering that the Johnson noise comprises noise from the gate metal and noise from the channel). Embodiments of the present invention are able to provide a HEMT having an RST contribution that is zero or at least two times smaller than the thermal noise arising from the channel (channel thermal noise) at 300 K and under low noise bias conditions (drain-source voltage, V_{DS}, and gate-source voltage, V_{GS}, selected to minimize noise).

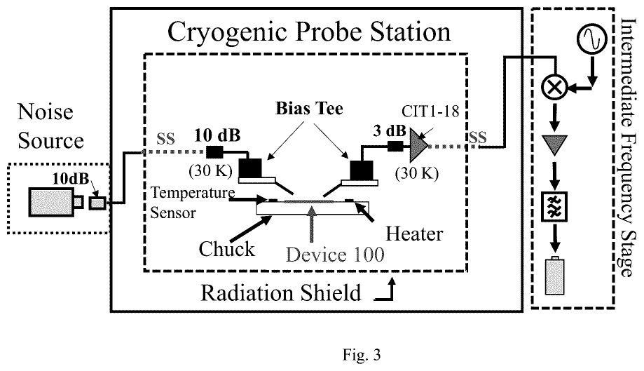

In other material systems (e.g., nitrides), if the offset (and optionally strain) is judiciously increased/selected, the RST noise can be similarly reduced. The impact on noise can be measured using the setup of FIG. 3 and the offset (alloy compositions) can be optimized or corrected based on the measurements.

### First Embodiment: InGaAs/InAlAs HEMT

For the example of InGaAs/InAlAs HEMTs, the aluminum (Al) content of the barrier plays a role in setting ΔE_{C}, with higher concentration of Al leading to higher ΔE_{C}. Currently, in the state-of-the-art devices, for a barrier comprising InₓAl₁₋ₓ As, where x is the Indium mole fraction, the barrier is lattice-matched to the lattice constant of the InP wafer, leading to x=0.52. The corresponding ΔE_{C} is around 0.5 eV.

In one example, the first semiconductor alloy comprises InGaAs, the second semiconductor alloy comprises InAlAs and the Al content of the InAlAs barrier is greater than 0.55. Increasing the barrier Al content to 0.55 and 0.62 leads to ΔE_{C} of 0.6 eV and 0.7 eV, respectively, resulting in a suppression of RST noise by 65% and 85%, respectively, relative to the typical case with 0.5 eV conduction band discontinuity.

Taking into account that the offset can depend on both the channel and barrier alloy compositions, a variety of offsets can be achieved. For a lattice matched channel and barrier, the offset is 0.5 eV, but for a lattice matched barrier and strained channel (most common case) the offset is around 0.6-0.7 eV. Using the strained barrier, we expect to increase the offset even more.

As an example of the impact on amplifier noise, reducing RST by 85% would lead to a ˜40% improvement in the noise temperature at room temperature and 12 GHz relative to state-of-art devices, as shown in the following analysis.

RST theory predicts T_{d} to exhibit an exponential dependence on Tₚₕ and V_{DS}. However, the measured trends vary less rapidly than predicted from RST alone. We therefore introduce a model of drain noise in which the noise arises from the sum of two components: one arising from thermal noise associated with the channel resistance and the other due to RST. T_{d} can then be expressed as:

T_{d}=Tₑ+T_{RST} (1)
where the RST noise temperature is given as

$${T}_{RST} = {T}_{RST}^{O} {e}^{- \frac{Δ {E}_{c} - q ( {V}_{GS} - {V}_{th} )}{{k}_{B} {T}_{e}}}$$

Here, q is the electric charge, k B the Boltzmann constant, V_{GS} the gate-source voltage, Vₜₕ the threshold voltage, ΔE_{C} the conduction band discontinuity. The temperature dependence of ΔE_{C} was omitted and was set to ˜0.5 eV at all Tₚₕ [24]. From (4) of [1],

T_{RST}^{o}=(q²v_{d1}²nₛ₁τγW)/(k_{B}g_{ds}L_{g}),
where v_{d1}˜4×10⁷ cm s⁻¹ is the saturation velocity in the channel [25], τ˜1 ps is the characteristic time of electrons to transfer from channel to barrier [26], nₛ₁ is the channel electron sheet density (typically ˜2×10¹² cm⁻² [27]), W is the gate width, g_{ds} the drain-source conductance extracted from the small-signal model, L_{g}˜70 nm the gate length, and γ is the probability of a hot electrons to emit from channel to barrier. For simplicity, it is assumed that all electrons with energy exceeding ΔE_{C} transfer to the barrier so that γ=1. The difference V_{GS}−Vₜₕ was given as V_{GS}−Vₜₕ˜94 mV, due to the constant V_{DS}=0.8 V and I_{DS}=20 mA at all Tₚₕ.

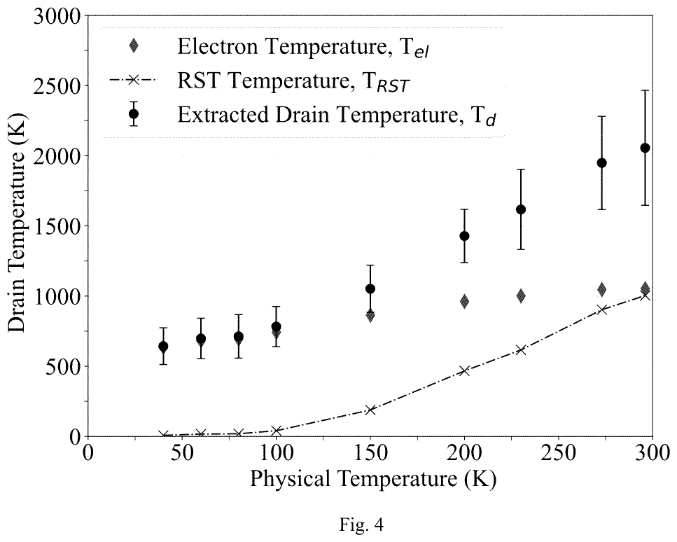

FIG. 4 shows the temperature dependence of T_{d} at various Tₚₕ from 40 K to 300 K at V_{DS}=0.8 V and I_{DS}=20 mA measured using the setup of FIG. 3. From the solution of (1), the individual contributions of thermal and RST to T_{d} are separated and plotted. A linear dependence of Tₑ on Tₚₕ is observed, with Tₑ increasing by ˜250 K as Tₚₕ is increased from 40 K to 300 K. The RST temperature, T_{RST}, follows a superlinear trend with Tₚₕ, varying from ˜300 K to ˜2000 K over the same physical temperature range. T_{RST} monotonically increases as the physical temperature increases.

With a physical model for drain noise, we estimate the magnitude of improvement in T₅₀ if the RST contribution were suppressed by improved confinement of electrons in the quantum well. In FIGS. 5a and 5b we plot the measured T₅₀ versus V_{DS} as at 40 K and 300 K. In each of these plots, we also show the predicted trend of T₅₀ if RST were absent so that drain noise was purely due to thermal noise from the channel resistance. These curves are obtained by setting T_{d}=Tₑ in our noise model. At 40 K, the measured and predicted T₅₀ exhibit a negligible difference for V_{DS}≲0.6 V, but at higher V as the predicted T₅₀ is markedly less than the measured value owing to the lack of noise from RST. The minimum of T₅₀ at 40 K would improve by ˜5% if RST were suppressed. At 300 K, the difference between measured and predicted T₅₀

In FIG. 5c the measured and predicted T₅₀ are plotted versus Tₚₕ at constant V_{DS}=0.8 V, I_{DS}=20 mA and frequency of 12 GHz. We observe that under these bias conditions, if the contribution of RST to T_{d} is suppressed, T₅₀ could improve by ˜4 K for Tₚₕ≲100 K and up to ˜25 K at Tₚₕ=300 K.

### Second Embodiment: Receiver and Low Noise Amplifier Comprising a HEMT with Reduced RST Noise at Microwave Frequencies

Receivers with HEMTs having the low noise figures described herein at room temperature would enable numerous applications in radio astronomy, deep space or satellite communications, planetary/earth science, remote sensing, weather monitoring/moisture absorption, radar, defense/warfare applications, detection of space debris, or any application for measuring microwave power.

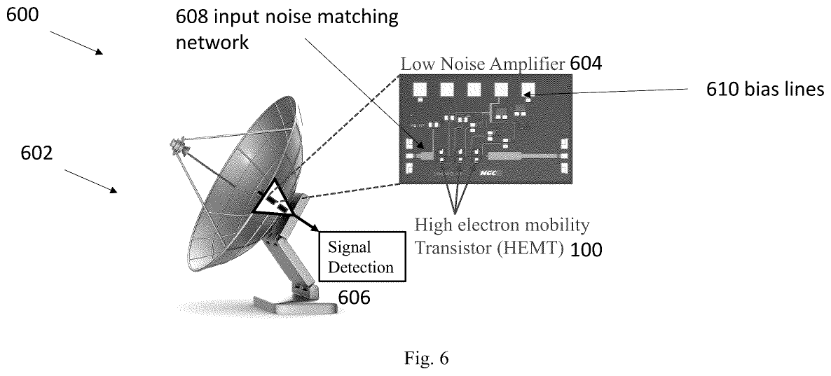

FIG. 6 illustrates an example low noise receiver circuit 600 comprising an antenna 602 outputting a microwave signal in response to microwave radiation; an amplifier circuit 604 comprising a HEMT 100 amplifying the microwave signal to form an amplified microwave signal; and a detector 606 for detecting the amplified microwave signal. The amplifier circuit 604 (e.g., integrated circuit) comprises an input noise matching network 608 and bias lines 610 (for applying gate-source voltage V_{GS} and drain source voltage V_{SD}) connected to the HEMT. The input noise matching network 608 comprises a noise impedance matched to the optimal noise impedance of the HEMT having zero RST noise or RST noise reduced (e.g., at least two times smaller than) channel thermal noise of the HEMT at 300 K and under low noise bias conditions (drain-source voltage, V_{DS}, and gate-source voltage, V_{GS}, selected to minimize noise). Although the reduced RST noise may be more pronounced at 300 K, a HEMT according to one or more embodiments may also benefit applications at lower (e.g., cryogenic) temperatures.

In one or more examples, the input noise matching network 608 comprises a transmission line whose impedance is appropriately selected. In one or more embodiments, input matching is the process of adjusting the input impedance (this includes selection of the right capacitors but is usually implied) so that the optimum impedance of the transistor (i.e., the input impedance for which the HEMT has lowest noise) is seen as a 50 Ohm—i.e., if we look into the matching network from left, we will see 50 Ohm even though at the right end of the matching network we have the optimum noise impedance.

In one or more embodiments, the input noise matching network 608 comprises a transmission line whose impedance and capacitance is appropriately selected, and/or the transmission line structure is designed to match the external 50 Ohms to the optimal impedance of the HEMT which yields the lowest noise.

Example Process Steps

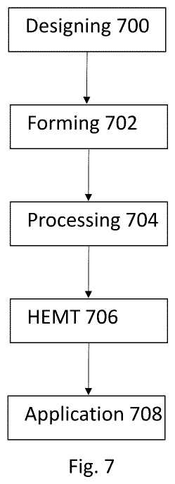

FIG. 7 illustrates a method of making a HEMT comprising the following steps.

Block 700 represents designing the HEMT. The designing comprises selecting, for the channel, a first semiconductor alloy and a first alloy composition of the first semiconductor alloy comprising a first conduction band energy. The designing further comprises selecting, for the barrier, a second semiconductor alloy and a second alloy composition of the second semiconductor alloy comprising a second conduction band energy, so that an offset between the first conduction band energy and the second conduction band energy confines mobile charge carriers in the channel and so that the HEMT has a desired RST below a certain threshold. The first alloy composition and the second alloy composition can be selected so that both the first semiconductor alloy (channel) and the second semiconductor alloy (barrier) are strained (e.g., with respect to the substrate, e.g., Indium Phosphide) and the offset is increased to a desired level to reduce or eliminate the RST noise.

The method can optionally comprise fabricating the HEMT.

Block 702 represents depositing a heterostructure comprising the channel (channel layer) and the barrier (barrier layer) on a substrate, e.g., on a buffer on a substrate, and so that a heterojunction between the channel and the barrier is formed.

Block 702 represents forming contacts to the heterostructure. The forming comprises depositing a drain contact to the channel; a source contact to the channel; and coupling a gate contact coupled to the channel.

Block 704 represents optional further processing and/or HEMT formation steps, as known in the art.

Block 706 represents the end result, a HEMT. Illustrative embodiments of the HEMT include, but are not limited to, the following (referring also to FIGS. 1-7).
1. A high electron mobility transistor (HEMT) 100, comprising:
a channel 102 comprising a first semiconductor alloy comprising a first conduction band energy;
a barrier 104 comprising a second semiconductor alloy comprising a second conduction band energy, wherein an offset ΔEc between the first conduction band energy and the second conduction band energy confines mobile charge carriers in the channel;
a drain contact 108 to the channel;
a source contact 110 to the channel; and
a gate contact 112 coupled to the channel and modulating a current, comprising the mobile charge carriers flowing in response to a voltage V_{SD} applied between the source contact and the drain contact, when an RF signal electric field and DC bias electric field are applied between the gate contact and the source contact; and
the first semiconductor alloy comprises a first alloy composition and the second semiconductor alloy comprises a second alloy composition wherein the offset is increased to a level that suppresses real space transfer noise associated with a portion of the mobile charge carriers being thermionically emitted out of the channel into the barrier when the V_{SD} is applied, wherein the RST noise is reduced by at least a factor of two as compared to a HEMT where the alloy composition of the barrier is lattice matched (e.g., to the substrate, or to InP or In_{0.52}Al_{0.48}As in the case of an InGaAs/InAlAs HEMT).
2. A high electron mobility transistor (HEMT) 100, comprising:
a channel 102 comprising InGaAs comprising a first conduction band energy;
an barrier 104 comprising a InAlAs comprising a second conduction band energy; wherein an Al content of the InAlAs barrier is greater than 0.55;
a drain contact 108 to the channel;
a source contact 110 to the channel; and
a gate contact 112 coupled to the channel and modulating a current, comprising mobile charge carriers confined in the channel flowing in response to a voltage V_{SD} applied between the source contact and the drain contact, when an RF signal electric field and DC bias electric field are applied between the gate contact and the source contact.
3. A transistor 100, comprising:
a channel 102 comprising a first semiconductor alloy comprising a first conduction band energy;
a barrier 104 comprising a second semiconductor alloy comprising a second conduction band energy, wherein an offset between the first conduction band energy and the second conduction band energy confines mobile charge carriers in the channel;
a drain contact 108 to the channel;
a source contact 110 to the channel; and
a gate contact 112 coupled to the channel and modulating a current, comprising the mobile charge carriers flowing in response to a voltage V_{SD} applied between the source contact and the drain contact, when an RF signal electric field and DC bias electric field are applied between the gate contact and the source contact; and
wherein the first semiconductor alloy and the second semiconductor alloy each comprise an alloy composition wherein the offset ΔEc is such that the transistor has a microwave noise temperature at 6 GHz of at least 7K for V_{SD} in a range of 0.1-1.2 V and Tph of 300K, when the transistor is optimally noise matched to a 50 Ohm load and the RF signal electric field is 1-20 GHz.
4. The transistor of any of the embodiments 1-3, wherein the Al content is in a range of 0.55-0.8.
5. The transistor of any of the embodiments 1-4, wherein:
the transistor is grown on a buffer 114 on InP (e.g., substrate 116) and the barrier is strained with respect to the InP and the buffer comprises a uniform composition of In_{0.52}Al_{0.48}As, or
the transistor is grown on a graded buffer layer whose final composition is In_{0.52}Al_{0.48}As.
6. The transistor of any of the embodiments 1-5 wherein the transistor has a microwave noise temperature at 6 GHz of at least 7K (upper limit of 14K) for V_{SD} in a range of 0.1-1.2 V and Tₚₕ of 300K, when the transistor is optimally noise matched to a 50 Ohm load and the RF signal electric field is 1-20 GHz.
7. The transistor of any of the embodiments 1-6, wherein the transistor has a gate length of 5 nm-1000 nm and a distance between the source contact and the drain contact of 1 micrometer-3 micrometers.
8. The transistor of any of the embodiments 1-7, wherein the offset ΔEc between the first conduction band and the second conduction band is in a range of 0.6-1.0 eV.
9. The transistor of any of the embodiments 1, 3-8 wherein the channel comprises GaN and the barrier comprises AlGaN.
10. The transistor of any of the embodiments 1-8, wherein the barrier comprises InAlAs and the channel comprises InGaAs.

Block 708 represents optionally connecting the HEMT in an application (e.g., receiver) or circuit (e.g., amplifier circuit), e.g., integrated circuit.
11. A low noise microwave receiver amplifier 7-2, or readout circuit for a quantum computer comprising the HEMT of claim 1.
12. An amplifier circuit 604 useful for amplifying a microwave signal to form an amplified microwave signal, comprising:
an input noise matching network 608 (e.g., comprising circuitry) connected to a HEMT, wherein the input noise matching network comprises a noise impedance matched to an optimal noise impedance of the HEMT having an RST noise, at 300K, at least two times smaller than channel thermal noise of the HEMT at microwave frequencies (e.g., 1-20 GHz) and under low noise bias conditions (defined as drain-source voltage, V_{DS}, and gate-source voltage, V_{GS}, selected to minimize noise).
13. The amplifier of embodiment 12 comprising the HEMT of any of the embodiments 1-11.
14. The HEMT of any of the embodiments 1-11 having the offset and alloy compositions selected so that the RST noise, at 300 Kelvin, is reduced as compared to (at least two times smaller than) channel thermal noise of the HEMT at microwave frequencies (e.g., 1-20 GHz) and under low noise bias conditions (defined as drain-source voltage, V_{DS}, and gate-source voltage, V_{GS}, selected to minimize noise).
15. The amplifier circuit of any of the embodiments 11-14, wherein the input noise matching network 608 comprises a transmission line whose impedance and capacitance is appropriately selected, and/or comprises a transmission line structure designed to match the external 50 Ohms to the optimal impedance of the HEMT which yields the lowest noise.
16. The amplifier circuit of any of the embodiments 11-15 further comprising a chip or package or integrated circuit comprising the amplifier circuit.
17. A method of making a HEMT, comprising:
selecting the alloy composition of the channel comprising the first semiconductor alloy comprising a first conduction band energy;
selecting the alloy composition of the barrier comprising the second semiconductor alloy comprising a second conduction band energy, wherein an offset between the first conduction band energy and the second conduction band energy confines mobile charge carriers in the channel; so that when the HEMT comprising the channel, the barrier, the drain contact to the channel; the source contact to the channel; and a gate contact coupled to the channel is made:
the gate contact modulates a current, comprising the mobile charge carriers flowing in response to a voltage V_{SD} applied between the source contact and the drain contact, when an RF signal electric field and DC bias electric field are applied between the gate contact and the source contact; and
the real space transfer noise, associated with a portion of the mobile charge carriers being thermionically emitted out of the channel into the barrier when the V_{SD} is applied, is reduced by at least a factor of two as compared to a HEMT where the alloy composition of the barrier is lattice matched.
18. The HEMT of any of the embodiments 1-16 fabricated using the method of embodiment 17.

### REFERENCES

The following references are incorporated by reference herein.
[1] Further information on one or more embodiments of the present invention can be found in “A Physical Model for Drain Noise in High Electron Mobility Transistors: Theory and Experiment,” by Bekari Gabritchidze, Kieran A. Cleary, Anthony C. Readhead, Austin J. Minnich, arXiv:2209.02858v2, https://doi.org/10.48550/arXiv.2209.02858.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A high electron mobility transistor (HEMT), comprising:
a channel comprising a first semiconductor alloy comprising a first conduction band energy;
a barrier comprising a second semiconductor alloy comprising a second conduction band energy, wherein an offset between the first conduction band energy and the second conduction band energy confines mobile charge carriers in the channel;
a drain contact to the channel;
a source contact to the channel; and
a gate contact coupled to the channel and modulating a current, comprising the mobile charge carriers flowing in response to a voltage V_{SD} applied between the source contact and the drain contact, when an RF signal electric field and DC bias electric field are applied between the gate contact and the source contact; and
the first semiconductor alloy comprises a first alloy composition and the second semiconductor alloy comprises a second alloy composition selected so that the offset is increased to a level that suppresses real space transfer noise associated with a portion of the mobile charge carriers being thermionically emitted out of the channel into the barrier when the V_{SD} is applied, wherein the RST noise is reduced by at least a factor of two as compared to a HEMT where the alloy composition of the barrier is lattice matched.

2. The transistor of claim 1, wherein the offset between the first conduction band and the second conduction band is in a range of 0.6-1.0 eV.

3. The transistor of claim 1, wherein the channel comprises GaN and the barrier comprises AlGaN.

4. A high electron mobility transistor (HEMT), comprising:
a channel comprising InGaAs comprising a first conduction band energy;
an barrier comprising a InAlAs comprising a second conduction band energy;
wherein an Al content of the InAlAs barrier is greater than 0.55;
a drain contact to the channel;
a source contact to the channel; and
a gate contact coupled to the channel and modulating a current, comprising mobile charge carriers confined in the channel flowing in response to a voltage V_{SD} applied between the source contact and the drain contact, when an RF signal electric field and DC bias electric field are applied between the gate contact and the source contact.

5. The transistor of claim 4, wherein the Al content is in a range of 0.55-0.8.

6. The transistor of claim 3, wherein:
the transistor is grown on a buffer on InP and the barrier is strained with respect to the InP and the buffer comprises a uniform composition of In_{0.52}Al_{0.48}As, or
the transistor is grown on a graded buffer layer whose final composition is In_{0.52}Al_{0.48}As.

7. The transistor of claim 1, wherein the transistor has a microwave noise temperature at 6 GHz of at least 7K (upper limit of 14K) for V_{SD} in a range of 0.1-1.2 V and Tph of 300K, when the transistor is optimally noise matched to a 50 Ohm load and the RF signal electric field is 1-20 GHz.

8. The transistor of claim 7, wherein the transistor has a gate length of 5 nm-1000 nm and a distance between the source contact and the drain contact of 1 micrometer-3 micrometers.

9. A low noise microwave receiver amplifier, or readout circuit for a quantum computer comprising the HEMT of claim 1.

10. The transistor of claim 1, wherein the RST noise is at least two times smaller than the HEMT's channel thermal noise at 300 K under low noise bias conditions and at microwave frequencies in a range of 1-20 GHz.

11. An amplifier circuit useful for amplifying a microwave signal to form an
amplified microwave signal, comprising:
an input noise matching network connected to a HEMT, wherein the input noise matching network comprises a noise impedance matched to an optimal noise impedance of the HEMT having an RST noise, at 300 K, at least two times smaller than the HEMT's channel thermal noise (at 300 K) at microwave frequencies and under low noise bias conditions.

12. The amplifier circuit of claim 11, wherein:
the HEMT comprises a heterostructure grown on a buffer on InP and the barrier is strained with respect to the InP and the buffer comprises a uniform composition of In_{0.52}Al_{0.48}As, or
the HEMT comprises a heterostructure grown on a graded buffer layer whose final composition is In_{0.52}Al_{0.48}As.

13. The amplifier circuit of claim 11, wherein the HEMT comprises a channel comprising a first alloy composition forming a heterojunction with a barrier comprising a second alloy composition so that the HEMT comprises a microwave noise temperature at 6 GHz of at least 7K for V_{SD} in a range of 0.1-1.2 V and Tₚₕ of 300K, when the transistor is optimally noise matched to a 50 Ohm load and the RF signal electric field is 1-20 GHz.

14. The amplifier circuit of claim 13, wherein the HEMT comprises a gate length of 5 nm-1000 nm and a distance between the source contact and the drain contact of 1 micrometer-3 micrometers.

15. The amplifier circuit of claim 11, wherein the HEMT comprises a barrier comprising InAlAs and a channel comprising InGaAs.

16. The amplifier circuit of claim 11, wherein the HEMT comprises gallium nitride.

17. The amplifier circuit of claim 11, wherein the microwave frequencies in a range of 1-20 GHz and the low noise bias conditions comprise drain-source voltage, V_{DS}, and gate-source voltage, V_{GS}, selected to minimize noise.

18. The amplifier circuit of claim 11, wherein the HEMT comprises:
a channel comprising a first semiconductor alloy comprising a first conduction band energy;
a barrier comprising a second semiconductor alloy comprising a second conduction band energy, wherein an offset between the first conduction band energy and the second conduction band energy confines mobile charge carriers in the channel;
a drain contact to the channel;
a source contact to the channel; and
a gate contact coupled to the channel and modulating a current, comprising the mobile charge carriers flowing in response to a voltage V_{SD} applied between the source contact and the drain contact, when an RF signal electric field and DC bias electric field are applied between the gate contact and the source contact; and
wherein the first semiconductor alloy and the second semiconductor alloy each comprise an alloy composition wherein the offset is such that the transistor has a microwave noise temperature at 6 GHz of at least 7K for V_{SD} in a range of 0.1-1.2 V and Tph of 300K, when the transistor is optimally noise matched to a 50 Ohm load and the RF signal electric field is 1-20 GHz.

19. The amplifier circuit of claim 18, wherein the barrier comprises InAlAs and the channel comprises InGaAs.
